(19) United States
(12) Patent Application Publication
(10) Pub. No.: US 2026/0372162 A1
(43) Pub. Date: Nov. 19, 2026

(54) SEMICONDUCTOR DEVICE AND SEMICONDUCTOR DEVICE MANUFACTURING METHOD

(71) Applicant: SHINKO ELECTRIC INDUSTRIES CO., LTD., Nagano-shi (JP)

(72) Inventor: Seiji Sato, Nagano (JP)

(21) Appl. No.: 19/569,255

(22) Filed: Mar. 17, 2026

(30) Foreign Application Priority Data
Mar. 21, 2025 (JP) 2025-047323

(51) Int. Cl. H10W 72/00; H10W 70/00; H10W 70/655; H10W 70/685; H10W 74/15; H10W 90/00

(52) U.S. Cl. CPC H10W 72/823; H10W 70/099; H10W 70/655; H10W 70/687; H10W 90/401; H10W 74/15; H10W 90/724

(57) ABSTRACT

A semiconductor device includes a first wiring board, an electronic component, a second wiring board facing the first wiring board across the electronic component, and a connection member being an integrated body of conductive balls and the second wiring board, and connecting the first wiring board and the second wiring board. The first wiring board includes a wiring layer including a pad to which a conductive ball that forms the connection member is bonded, a first insulating layer covering the wiring layer and including a first opening for exposing the pad, and a second insulating layer being laminated on the first insulating layer, and including a second opening for exposing the pad and a surface of the first insulating layer around the first opening and a third opening for exposing a surface of the first insulating layer at a different position from the second opening.

### CROSS-REFERENCE TO RELATED APPLICATION

This application is based upon and claims the benefit of priority of the prior Japanese Patent Application No. 2025-047323, filed on Mar. 21, 2025, the entire contents of which are incorporated herein by reference.

### FIELD

The embodiments discussed herein is related to a semiconductor device and a semiconductor device manufacturing method.

### BACKGROUND

In recent years, to realize high density component mounting, for example, a semiconductor device that is configured to incorporate an electronic component, such as a semiconductor chip, into a substrate is attracting attention. The semiconductor device as described above includes, for example, two wiring boards and is configured such that an electronic component, such as a semiconductor chip, is mounted on one of the wiring boards and the electronic components is sandwiched between the one of the wiring boards and the other one of the wiring boards.

The two wiring boards are connected to each other by a connection member. Specifically, a conductive ball, such as a solder ball, that is bonded to a pad of one of the two wiring boards is arranged on a pad of the other wiring board and is melted by heat and pressure so as to be bonded to the pad of the other wiring board. Accordingly, the two wiring boards are connected to each other by the connection member that is configured with the conductive ball.

Furthermore, there is a known semiconductor device in which two solder resist layers that include openings at positions of pads included in wiring layers are formed on a surface of a wiring board.

Patent Literature 1: U.S. Pat. No. 5,058,929

Patent Literature 2: Japanese Laid-open Patent Publication No. 2020-96041

Meanwhile, in the semiconductor device in which the electronic component is incorporated, a diameter of the conductive ball that forms the connection member is determined by taking into account a thickness of the electronic component that is sandwiched between the two wiring boards. In this case, a length of the connection member that connects the two wiring boards may increase and the diameter of the conductive ball may increase with increase in the thickness of the electronic component that is sandwiched between the two wiring boards.

In contrast, to prevent increase in the diameter of a single conductive ball, it may be possible to mount a conductive ball on each of the two wiring boards and connect the two wiring boards by a connection member that is obtained by melting the conductive balls that are mounted on the two respective wiring boards and integrating the conductive balls. To infallibly connecting the two wiring boards, it is important to measure a height of the conductive ball from a surface of a solder resist layer that is formed on a surface of the wiring board.

As a method of measuring the height of the conductive ball, a method using reflected light is known. In this method, it is possible to calculate the height of the conductive ball from a reference surface by applying light to each of the surface of the solder resist layer that serves as the reference surface for height measurement and the conductive ball and measuring a value related to a height of the reference surface and a value related to the height of the conductive ball by using the reflected light.

Here, when the two solder resist layers as described above are formed on the surface of the wiring board, a surface of the solder resist layer on a lower side between the two solder resist layers is used as the reference surface, and the height of the conductive ball from the reference surface is measured. In this case, the value related to the height of the reference surface is measured by using reflected light from the surface of the lower solder resist layer around an opening of the lower solder resist layer that is exposed from an opening of a solder resist layer on an upper side between the two solder resist layers.

However, it is difficult to measure the value related to the height of the reference surface by using the reflected light with respect to the surface of the lower solder resist layer exposed from the opening of the upper solder resist layer, which is a problem. Specifically, with respect to the surface of the lower solder resist layer exposed from the opening of the upper solder resist layer, an area is relatively small and the applied light is blocked by the conductive ball, so that it is difficult to appropriately measure the value related to the height of the reference surface by the method using the reflected light. As a result, when the two solder resist layers are formed on the surface of the wiring board, it is difficult to measure the height of the conductive ball from the reference surface with high accuracy.

### SUMMARY

According to an aspect of an embodiment, a semiconductor device includes a first wiring board; an electronic component that is arranged on the first wiring board; a second wiring board that faces the first wiring board across the electronic component; and a connection member that is an integrated body of conductive balls that are mounted on the first wiring board and the second wiring board, respectively, and connects the first wiring board and the second wiring board, wherein the first wiring board includes a wiring layer that includes a pad to which a conductive ball that forms the connection member is bonded; a first insulating layer that covers the wiring layer and includes a first opening for exposing the pad; and a second insulating layer that is laminated on the first insulating layer, and includes a second opening for exposing the pad and a surface of the first insulating layer around the first opening; and a third opening for exposing a surface of the first insulating layer at a different position from the second opening.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic cross-sectional view illustrating a configuration of a semiconductor device according to one embodiment;

FIG. 2 is a plan view illustrating the configuration of the semiconductor device according to one embodiment;

FIG. 3 is a flowchart illustrating a method of manufacturing a first wiring board according to one embodiment;

FIG. 4 is a schematic diagram illustrating a cross section of the first wiring board;

FIG. 5 is a diagram for explaining a second protective insulating layer formation process;

FIG. 6 is a diagram for explaining a solder ball mounting process;

FIG. 7 is a diagram for explaining mounting of an electronic component;

FIG. 8 is a flowchart illustrating a ball height measurement process according to one embodiment;

FIG. 9 is a flowchart illustrating a second wiring board manufacturing method according to one embodiment;

FIG. 10 is a schematic diagram illustrating a cross section of a second wiring board;

FIG. 11 is a diagram for explaining a solder ball mounting process;

FIG. 12 is a flowchart illustrating a semiconductor device manufacturing method according to one embodiment;

FIG. 13 is a diagram for explaining lamination of the first wiring board and the second wiring board;

FIG. 14 is a diagram for explaining a bonding process;

FIG. 15 is a diagram for explaining a molding process;

FIG. 16 is a diagram for explaining a dicing process;

FIG. 17 is a plan view illustrating a configuration of a semiconductor device according to a first modification of one embodiment;

FIG. 18 is a plan view illustrating a configuration of a semiconductor device according to a second modification of one embodiment; and

FIG. 19 is a plan view illustrating a configuration of a semiconductor device according to a third modification of one embodiment.

### DESCRIPTION OF EMBODIMENT

Embodiment of a semiconductor device disclosed in the present application will be described in detail below based on the drawings. Meanwhile, the disclosed technology is not limited by the embodiment below.

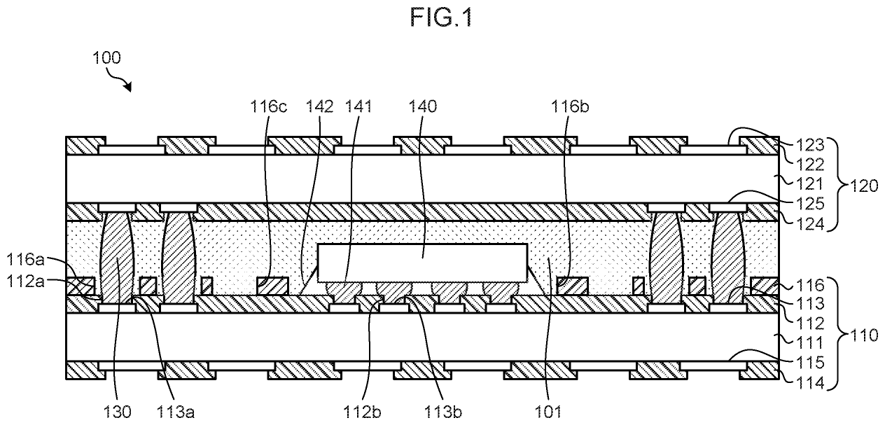

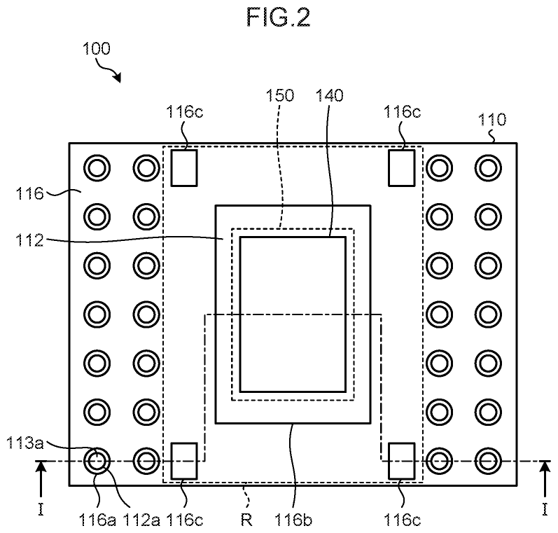

FIG. 1 is a schematic cross-sectional view illustrating a configuration of a semiconductor device 100 according to one embodiment. FIG. 2 is a plan view illustrating the configuration of the semiconductor device 100 according to one embodiment. FIG. 1 schematically illustrates a cross section of the semiconductor device 100 taken along a line I-I in FIG. 2. Further, in FIG. 2, for convenience of explanation, illustration of a second wiring board 120 and a connection member 130 of the semiconductor device 100 are omitted.

Meanwhile, in the following, for the sake of convenience, a direction from a first wiring board 110 toward the second wiring board 120 is referred to as an upward direction, a direction from the second wiring board 120 toward the first wiring board 110 is referred to as a downward direction, and a vertical direction of the semiconductor device 100 is defined based on the upward direction and the downward direction. However, the semiconductor device 100 may be manufactured and used upside down, and may be manufactured and used in arbitrary posture, for example.

The semiconductor device 100 illustrated in FIG. 1 includes the first wiring board 110 and the second wiring board 120 that are laminated one on top of the other, and sealing resin 101 that covers an electronic component 140 that is arranged so as to be sandwiched between the first wiring board 110 and the second wiring board 120. Specifically, the semiconductor device 100 is configured such that the first wiring board 110 and the second wiring board 120 are connected to each other by the connection member 130. The connection member 130 is an integrated body that is obtained by integrating solder balls that are mounted on the first wiring board 110 and the second wiring board 120. Further, the electronic component 140 is mounted on a surface of the first wiring board 110, where the electronic component 140 is sandwiched between the first wiring board 110 and the second wiring board 120 and covered by the sealing resin 101.

The sealing resin 101 is insulating resin, such as thermosetting epoxy resin, that contains inorganic filler, such as alumina, silica, aluminum nitride, or silicon carbide, for example. The electronic component 140 is, for example, a semiconductor chip.

The first wiring board 110 includes a substrate 111, a first protective insulating layer 112 (one example of a first insulating layer), an upper pad 113, a solder resist layer 114, a lower pad 115, and a second protective insulating layer 116 (one example of a second insulating layer). Meanwhile, although not illustrated in FIG. 1, the upper pad 113 and the lower pad 115 are electrically connected to each other by via wiring that is arranged in the substrate 111.

The substrate 111 is an insulating plate member and serves as a base material of the first wiring board 110. As a material of the substrate 111, for example, it may be possible to use glass epoxy resin that is obtained by impregnating glass cloth (glass woven fabric) that is a reinforcing member with thermosetting insulating resin that consists mainly of epoxy resin. The reinforcing member is not limited to the glass cloth, but it may be possible to use, for example, glass non-woven fabric, aramid woven fabric, aramid non-woven fabric, liquid crystal polymer (LCP) woven fabric, LCP non-woven fabric, or the like. Furthermore, as the thermosetting insulating resin, it may be possible to use, for example, polyimide resin, cyanate ester resin, or the like, instead of epoxy resin. On both surfaces of the substrate 111, wiring layers including the upper pad 113 and the lower pad 115 are formed. As a material of the wiring layers, for example, copper or copper alloy may be used.

Meanwhile, the substrate 111 is not limited to a single-layered insulating member, but may be a laminated substrate with a multi-layer structure in which an insulating layer and wiring layers are laminated. When the substrate 111 is the laminated substrate, the wiring layers sandwiching the insulating layer are electrically connected to each other by a via that penetrates through the insulating layer. As a material of the insulating layer, for example, insulating resin, such as epoxy resin or polyimide resin, or a resin material that is obtained by mixing filler, such as silica or alumina, in the resin may be used. Further, as a material of the wiring layer, for example, copper (Cu) or copper alloy may be used.

The first protective insulating layer 112 is an insulating layer that covers the wiring layer including the upper pad 113 on an upper surface of the substrate 111. At a position at which the connection member 130 of the first protective insulating layer 112 is formed, an opening 112a (one example of a first opening) is arranged, and an upper pad 113a for connecting the connection member 130 in the upper pad 113 is exposed from the opening 112a. Further, an opening 112b is arranged in a mounting region 150 (see FIG. 2) in which the electronic component 140 is mounted on a surface of the first protective insulating layer 112, and an upper pad 113b for mounting the electronic component 140 in the upper pad 113 is exposed from the opening 112b. As a material of the first protective insulating layer 112, for example, insulating resin, such as epoxy resin or acrylic resin, may be used.

The upper pad 113 is formed on the wiring layer on the upper surface of the substrate 111, and exposed from the openings of the first protective insulating layer 112 for connecting the connection member 130 and mounting the electronic component 140. Specifically, the connection member 130 is connected to the upper pad 113a in the upper pad 113. The connection member 130 bonds the first wiring board 110 and the second wiring board 120. Before the first wiring board 110 and the second wiring board 120 are bonded together, a solder ball that forms the connection member 130 is bonded to the upper pad 113a. Further, the electronic component 140 is connected to the upper pad 113b of the upper pad 113. Specifically, for example, the electronic component 140 is connected to the upper pad 113b by flip-chip bonding by solder bumps 141. Furthermore, a gap between the first wiring board 110 and the electronic component 140 is filled with an underfill material 142. As a material of the upper pad 113, similarly to the wiring layer, for example, copper or copper alloy may be used.

The solder resist layer 114 is an insulating layer that covers the wiring layer including the lower pad 115 on a lower surface of the substrate 111. An opening is arranged in a part of the solder resist layer 114, and the lower pad 115 is exposed from the opening. As a material of the solder resist layer 114, for example, insulating resin, such as epoxy resin or acrylic resin, may be used.

The lower pad 115 is formed on the wiring layer on the lower surface of the substrate 111, and exposed from the openings of the solder resist layer 114 for forming an external connecting terminal. Specifically, an external connecting terminal (not illustrated), such as a solder ball, is formed on the lower pad 115, for example. As a material of the lower pad 115, similarly to the wiring layer, for example, copper or copper alloy may be used.

The second protective insulating layer 116 is an insulating layer that is laminated on the first protective insulating layer 112. An opening 116a (one example of a second opening) is formed in the second protective insulating layer 116, and the upper pad 113a and a surface of the first protective insulating layer 112 around the opening 112a are exposed from the opening 116a. Further, an opening 116b (one example of a fourth opening) is arranged in another part of the second protective insulating layer 116, and the mounting region 150 (see FIG. 2) on the surface of the first protective insulating layer 112 is exposed from the opening 116b. Furthermore, at a different position from the opening 116a of the second protective insulating layer 116, an opening 116c (one example of a third opening) is arranged and the surface of the first protective insulating layer 112 is exposed from the opening 116c. The surface of the first protective insulating layer 112 that is exposed from the opening 116c serves as the reference surface for measuring a height of the conductive ball that forms the connection member 130.

In this manner, in one embodiment, the opening 116c of the second protective insulating layer 116 exposes the surface of the first protective insulating layer 112 that serves as the reference surface for measuring the heights of the solder balls, at a different position from the opening 116a that exposes the surface of the first protective insulating layer 112 around the opening 112a. The surface of the first protective insulating layer 112 that is exposed from the opening 116c of the second protective insulating layer 116 is a region that has a relatively large area and that does not include an obstacle that blocks applied light. Therefore, when light is applied to the surface of the first protective insulating layer 112 exposed from the opening 116c, it is possible to appropriately measure the value related to the height of the reference surface by reflected light from the surface of the first protective insulating layer 112, so that it is possible to measure the height of the solder ball from the reference surface with high accuracy.

An area of the surface of the first protective insulating layer 112 that is exposed from the opening 116c is larger than an area of the surface of the first protective insulating layer 112 that is exposed from the opening 116a. With this configuration, it is possible to more appropriately measure the value related to the height of the reference surface by reflected light from the surface of the first protective insulating layer 112, so that it is possible to more accurately measure the height of the solder ball from the reference surface.

The position of the opening 116c will be described below with reference to FIG. 2.

As illustrated in FIG. 2, the opening 116c is formed at a position closer to the opening 116b relative to the openings 116a. In the example illustrated in FIG. 2, the mounting region 150 that is exposed from the opening 116b and the opening 116b is located in a central part of the first wiring board 110, and the opening 116a is located in an outer peripheral part that sandwiches the central part of the first wiring board 110. Therefore, the opening 116c is formed at the side of the central part of the first wiring board 110 relative to the opening 116a. A region that is sandwiched between the opening 116a and the opening 116b has a relatively large area, so that it is possible to easily ensure an opening width of the opening 116c. By forming the opening 116c at a position closer to the opening 116b relative to the opening 116a, the opening width of the opening 116c is increased and an area of the surface of the first protective insulating layer 112 exposed from the opening 116c is increased. With this configuration, it is possible to appropriately measure the value related to the height of the reference surface by reflected light from the surface of the first protective insulating layer 112, so that it is possible to more accurately measure the height of the solder ball from the reference surface.

Furthermore, the second protective insulating layer 116 may include the plurality of openings 116c (four in the example illustrated in FIG. 2) that are formed at different positions. With this configuration, it is possible to apply light to the surface of the first protective insulating layer 112 exposed from the plurality of openings 116c. When light is applied to the surface of the first protective insulating layer 112 exposed from the plurality of openings 116c, it is possible to measure the value related to the height of the reference surface by reflected light at each of the different positions of the plurality of openings 116c. Further, by calculating an average of the values that are related to the height of the reference surface and that are measured at the different positions of the plurality of openings 116c, it is possible to average the influence of inclination of the reference surface. As a result, even when the reference surface is inclined, it is possible to measure the heights of the solder balls from the reference surface with high accuracy.

Furthermore, it may be possible to include the plurality of upper pads 113a along two opposing sides of the surface of the first wiring board 110. In this case, the plurality of openings 112a are formed in the first protective insulating layer 112 so as to correspond to the respective upper pads 113a, and the plurality of openings 116a (four in the example illustrated in FIG. 2) are formed in the second protective insulating layer 116 so as to correspond to the respective openings 112a. The plurality of openings 116c (four in the example in FIG. 2) are formed in at least corner portions of a rectangular region R that is sandwiched between the upper pads 113a that are formed along one of the two opposing sides of the surface of the first wiring board 110 and the upper pads 113a that are formed along the other one of the two opposing sides. In other words, the plurality of openings 116c are formed in at least four corners of the region R on the surface of the first wiring board 110. With this configuration, it is possible to measure the value related to the height of the reference surface by reflected light, at the four corners of the region R. In the four corners of the region R, the reference surface is relatively easily inclined due to thickness variation in the first wiring board 110, warpage of the first wiring board 110, or the like, for example. By calculating an average of the values that are related to the height of the reference surface and that are measured at the four corners of the region R, it is possible to average the influence of inclination of the reference surface. As a result, even when the reference surface is inclined, it is possible to measure the height of the solder ball from the reference surface with high accuracy.

Referring back to FIG. 1, the second wiring board 120 includes a substrate 121, a solder resist layer 122, an upper pad 123, a protective insulating layer 124, and a lower pad 125. Meanwhile, although not illustrated in FIG. 1, the upper pad 123 and the lower pad 125 are electrically connected to each other by via wiring that is arranged in the substrate 121.

The substrate 121 is an insulating plate member and serves as a base material of the second wiring board 120. As a material of the substrate 121, for example, glass epoxy resin that is obtained by impregnating glass cloth (glass woven fabric) that is a reinforcing member with thermosetting insulating resin that consists mainly of epoxy resin. The reinforcing member is not limited to the glass cloth, but it may be possible to use, for example, glass non-woven fabric, aramid woven fabric, aramid non-woven fabric, LCP woven fabric, LCP non-woven fabric, or the like. Furthermore, as the thermosetting insulating resin, it may be possible to use, for example, polyimide resin, cyanate ester resin, or the like, instead of epoxy resin. On both surfaces of the substrate 121, wiring layers including the upper pad 123 and the lower pad 125 are formed. As a material of the wiring layers, for example, copper or copper alloy may be used.

Meanwhile, the substrate 121 is not limited to a single-layered insulating member, but may be a laminated substrate with a multi-layer structure in which an insulating layer and wiring layers are laminated. When the substrate 121 is the laminated substrate, the wiring layers sandwiching the insulating layer are electrically connected to each other by a via that penetrates through the insulating layer. As a material of the insulating layer, for example, insulating resin, such as epoxy resin or polyimide resin, or a resin material that is obtained by mixing filler, such as silica or alumina, in the resin may be used. Further, as a material of the wiring layer, for example, copper (Cu) or copper alloy may be used.

The solder resist layer 122 is an insulating layer that covers the upper pad 123 on an upper surface of the substrate 121. An opening is arranged in a part of the solder resist layer 122, and the upper pad 123 is exposed from the opening. As a material of the solder resist layer 122, for example, insulating resin, such as epoxy resin or acrylic resin, may be used.

The upper pad 123 is formed on the wiring layer on the upper surface of the substrate 121, and exposed from the opening of the solder resist layer 122 for forming an external connecting terminal. Specifically, an external connecting terminal (not illustrated), such as a solder ball, is formed on the upper pad 123, for example. As a material of the upper pad 123, similarly to the wiring layer, for example, copper or copper alloy may be used.

The protective insulating layer 124 is an insulating layer that covers the lower pad 125 on a lower surface of the substrate 121. An opening is arranged in a part of the protective insulating layer 124, and the lower pad 125 is exposed from the opening. As a material of the protective insulating layer 124, for example, insulating resin, such as epoxy resin or acrylic resin, may be used.

The lower pad 125 is formed on the wiring layer on a lower surface of the substrate 121, and exposed from the opening of the protective insulating layer 124 for connection with the connection member 130. Specifically, the connection member 130 is connected to the lower pad 125. The connection member 130 bonds the first wiring board 110 and the second wiring board 120. Before the first wiring board 110 and the second wiring board 120 are bonded together, a solder ball that forms the connection member 130 is bonded to the lower pad 125. As a material of the lower pad 125, similarly to the wiring layer, for example, copper or copper alloy may be used.

The connection member 130 is formed with, for example, a conductor, such as solder, and connects the first wiring board 110 and the second wiring board 120. Specifically, the connection member 130 is an integrated body that is obtained by integrating the solder ball that is mounted on the first wiring board 110 and the solder ball that is mounted on the second wiring board 120. The connection member 130 has a barrel shape in which a width of a lower end connected to the second wiring board 120 is larger than a width of an upper end connected to the first wiring board 110, and side surfaces bulge outward.

A method of manufacturing the semiconductor device 100 that is configured as described above will be described below. In the following, a method of manufacturing the first wiring board 110 and a method of manufacturing the second wiring board 120 will be first described, and thereafter, a method of manufacturing the semiconductor device 100 including the first wiring board 110 and the second wiring board 120 will be described.

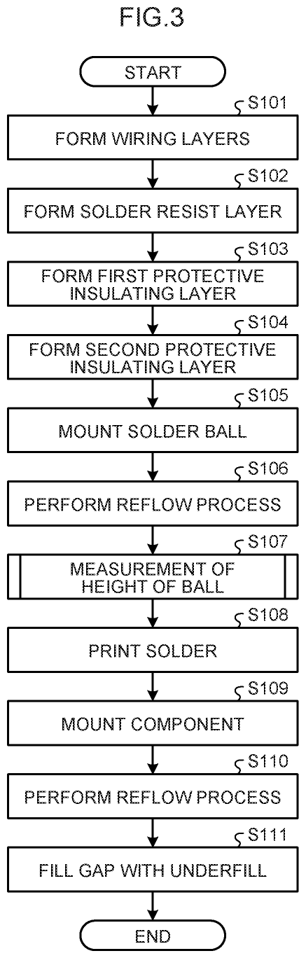

FIG. 3 is a flowchart illustrating the method of manufacturing the first wiring board 110 according to one embodiment.

Firstly, the wiring layers are formed on the upper surface and the lower surface of the substrate 111 (Step S101). Specifically, for example, the wiring layers are sequentially formed on the upper surface and the lower surface of the substrate 111 by the semi-additive method. The wiring layer on the upper surface of the substrate 111 includes the upper pad 113, and the wiring layer on the lower surface of the substrate 111 includes the lower pad 115. Further, the solder resist layer 114 that includes the opening at the position of the lower pad 115 is formed on the lower surface of the substrate 111 (Step S102), and the first protective insulating layer 112 that includes the opening at the position of the upper pad 113 is formed on the upper surface of the substrate 111 (Step S103). The first protective insulating layer 112 and the solder resist layer 114 are obtained by, for example, laminating photosensitive resin films or applying liquid or paste resin on the upper surface and the lower surface of the substrate 111 and performing patterning in a predetermined shape by exposure and developing on the laminated or applied resin by the photolithography method.

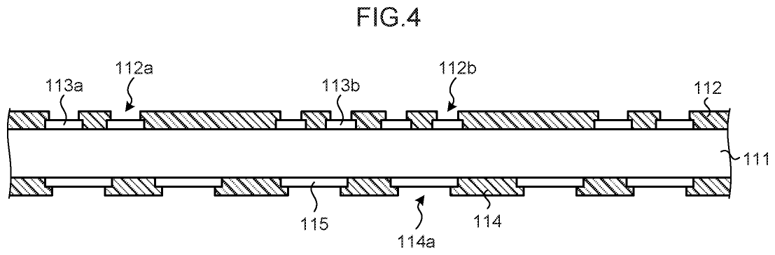

Through the processes as described above, as illustrated in FIG. 4 for example, the first wiring board 110 is formed in which the upper pads 113a and 113b are exposed from the openings 112a and 112b of the first protective insulating layer 112 on the upper surface of the substrate 111 and the lower pad 115 is exposed from an opening 114a of the solder resist layer 114 on the lower surface of the substrate 111. FIG. 4 is a schematic diagram illustrating a cross section of the first wiring board. The upper pad 113a is a pad that is connected to the connection member 130. The upper pad 113b is a pad that is connected to the electronic component 140 by flip-chip bonding. Areas in which the upper pads 113a and 113b are exposed may be different from each other.

After the first protective insulating layer 112 and the solder resist layer 114 are formed, the second protective insulating layer 116 that includes the opening at a position closer to the mounting region 150 relative to the position of the upper pad 113, relative to the position of the mounting region 150 (see FIG. 2), and relative to the upper pad 113 is formed on the upper surface of the first protective insulating layer 112 (Step S104). The second protective insulating layer 116 is obtained by, for example, laminating a photosensitive resin or applying liquid or paste resin on the upper surface of the first protective insulating layer 112 and performing patterning in a predetermined shape by exposure and developing on the laminated or applied resin by the photolithography method.

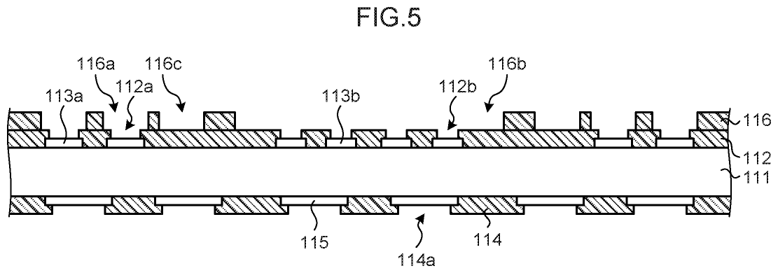

Through the processes as described above, as illustrated in FIG. 5 for example, on the upper surface of the first wiring board 110, the upper pad 113a and the surface of the first protective insulating layer 112 around the opening 112a are exposed from the opening 116a of the second protective insulating layer 116, and the mounting region 150 (see FIG. 2) on the surface of the first protective insulating layer 112 is exposed from the opening 116b of the second protective insulating layer 116. Furthermore, on the upper surface of the first wiring board 110, the surface of the first protective insulating layer 112 that serves as the reference surface for measuring the height of the solder ball that forms the connection member 130 is exposed from the opening 116c of the second protective insulating layer 116. FIG. 5 is a diagram for explaining a second protective insulating layer formation process.

After the second protective insulating layer 116 is formed, a solder ball 131 that are used for forming the connection member 130 is mounted at the position of the upper pad 113a (Step S105). Then, a reflow process is performed (Step S106), so that the solder ball 131 is bonded to the upper pad 113a.

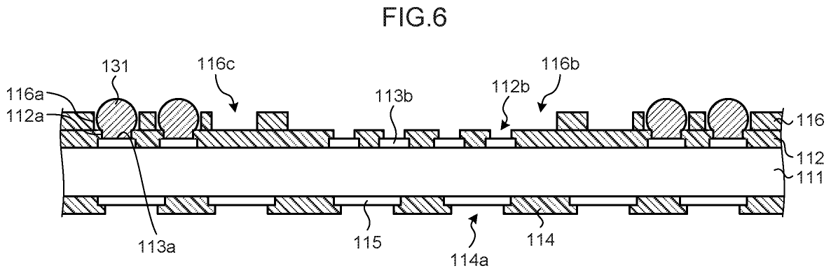

Through the processes as described above, as illustrated in FIG. 6 for example, the solder ball 131 (one example of a conductive ball) is bonded to the upper pad 113a. FIG. 6 is a diagram for explaining a solder ball mounting process.

After the solder ball 131 is bonded to the upper pad 113a, the height of the solder ball 131 is measured (Step S107). Specifically, light is applied to each of the surface of the first protective insulating layer 112 serving as the reference surface and the solder ball 131, a value related to the height of the reference surface and a value related to the height of the solder ball 131 are measured by using reflected light, and the height of the solder ball 131 from the reference surface are calculated. Meanwhile, a process of measuring the height of the solder ball 131 will be described in detail later.

Solder paste is printed on the upper pad 113b to mount the electronic component 140 (Step S108). Further, the electronic component 140 is mounted at the position of the upper pad 113b (Step S109). The electronic component 140 is subjected to a reflow process (Step S110), and mounted on the first wiring board 110. Furthermore, if needed, a gap between the electronic component 140 and the upper surface of the first wiring board 110 is filled with the underfill material 142 that is made of insulating resin (Step S111).

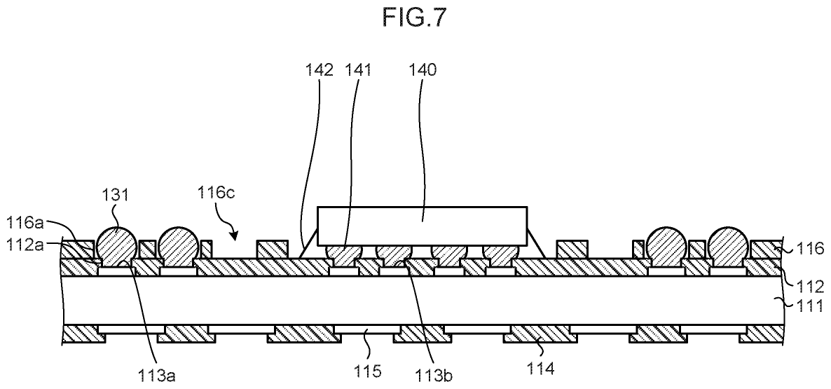

Through the processes as described above, as illustrated in FIG. 7 for example, the electronic component 140 that is connected to the upper pad 113b by flip-chip bonding by the solder bumps 141 is mounted on the upper surface of the first wiring board 110. With this configuration, the first wiring board 110 that forms the lower layer of the semiconductor device 100 is obtained. FIG. 7 is a diagram for explaining mounting of the electronic component 140.

Meanwhile, it is preferable to manufacture the first wiring board 110 as an assembly in which the plurality of first wiring boards 110 are arrayed, instead of being manufactured singly. In the assembly, for example, the first wiring boards 110 are manufactured in individual sections that are divided in a lattice pattern.

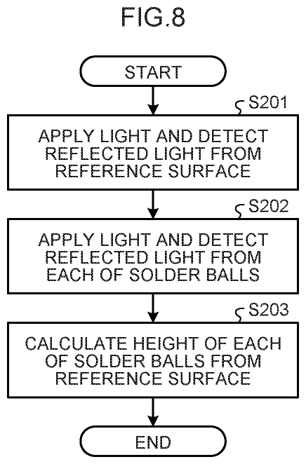

The process of measuring the heights of the solder balls 131 will be described in detail below with reference to FIG. 8. FIG. 8 is a flowchart illustrating a ball height measurement process according to one embodiment. The heights of the solder balls 131 are measured by, for example, a height measurement apparatus that includes a light source, an optical sensor, and a calculation apparatus.

After the solder ball 131 is bonded to the upper pad 113a, the light source emits light to the opening 116c of the second protective insulating layer 116, and the optical sensor detects reflected light from the reference surface, that is, the surface of the first protective insulating layer 112 exposed from the opening 116c (Step S201). When the optical sensor detects the reflected light from the reference surface, the value related to the height of the reference surface is measured. The value related to the height of the reference surface may be, for example, a distance from the optical sensor and the surface of the first protective insulating layer 112 exposed from the opening 116c. The value related to the height of the reference surface may be measured by using, for example, data that indicates a correspondence relation between intensity of the reflected light and the value related to the height of the reference surface.

Meanwhile, when the second protective insulating layer 116 includes the plurality of openings 116a, light is applied to the surface of the first protective insulating layer 112 exposed from the plurality of openings 116c, and the value related to the height of the reference surface is measured by the reflected light for each of the openings 116c. Further, an average of the values related to the height of the reference surface that are measured at different positions of the plurality of openings 116c is calculated.

Subsequently, the light source applies light to each of the solder balls 131, and the optical sensor detects reflected light from each of the solder balls 131 (Step S202). When the optical sensor detects the reflected light from each of the solder balls 131, a value related to a height of each of the solder balls 131 is measured. The value related to the height of each of the solder balls 131 may be, for example, a distance between the optical sensor and each of the solder balls 131. The value related to the height of each of the solder balls 131 may be measured by using, for example, data that indicates a correspondence relation between intensity of the reflected light and the values related to the heights of the solder balls 131.

Further, the calculation apparatus calculates the height of each of the solder balls 131 from the reference surface based on the value related to the height of the reference surface and the value related to the height of each of the solder balls 131 (Step S203).

In this manner, according to one embodiment, the opening 116c is formed in the second protective insulating layer 116 at a different position from the opening 116a corresponding to the position of the upper pad 113a bonded to the solder ball 131, and the surface of the first protective insulating layer 112 is exposed from the opening 116c. With this configuration, it is possible to use the surface of the first protective insulating layer 112 exposed from the opening 116c as the reference surface for measuring the height of the solder ball 131, so that it is possible to appropriately measure the value related to the height of the reference surface by using the reflected light from the reference surface. As a result, it is possible to measure the height of the solder ball 131 from the reference surface with high accuracy.

Meanwhile, when the height of the solder ball 131 from the reference surface is out of tolerance, it may be possible to remove the current solder ball 131 from the upper pad 113a and mount the different solder ball 131 on the upper pad 113a. Further, removal of the solder ball 131 and mounting of the different solder ball 131 may be performed repeatedly until the height of the solder ball 131 from the reference surface falls within the tolerance.

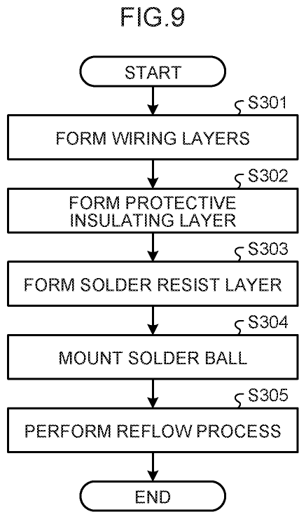

FIG. 9 is a flowchart illustrating a method of manufacturing the second wiring board 120 according to one embodiment.

Firstly, the wiring layers are formed on the upper surface and the lower surface of the substrate 121 (Step S301). Specifically, for example, the wiring layers are sequentially formed on the upper surface and the lower surface of the substrate 121 by the semi-additive method. The wiring layer on the upper surface of the substrate 121 includes the upper pad 123, and the wiring layer on the lower surface of the substrate 121 includes the lower pad 125. Further, the protective insulating layer 124 that includes the opening at the position of the lower pad 125 is formed on the lower surface of the substrate 121 (Step S302), and the solder resist layer 122 that includes the opening at the position of the upper pad 123 is formed on the upper surface of the substrate 121 (Step S303). The solder resist layer 122 and the protective insulating layer 124 are obtained by, for example, laminating photosensitive resin films or applying liquid or paste resin on the upper surface and the lower surface of the substrate 121 and performing patterning in a predetermined shape by exposure and developing on the laminated or applied resin by the photolithography method.

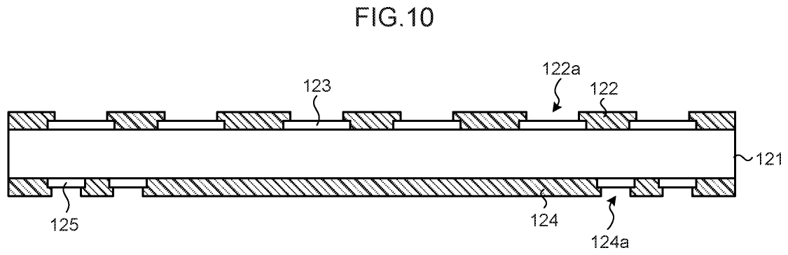

Through the processes as described above, as illustrated in FIG. 10 for example, the second wiring board 120 is formed in which the upper pad 123 is exposed from an opening 122a of the solder resist layer 122 on the upper surface of the substrate 121 and the lower pad 125 is exposed from an opening 124a of the protective insulating layer 124 on the lower surface of the substrate 121. FIG. 10 is a schematic diagram illustrating a cross section of the second wiring board. The lower pad 125 is a pad that is connected to the connection member 130.

The lower pad 125 is connected to the connection member 130, and solder ball 132 that is used for forming the connection member 130 is mounted at the position of the lower pad 125 (Step S304). Then, the reflow process is performed (Step S305), so that the solder ball 132 is bonded to the lower pad 125.

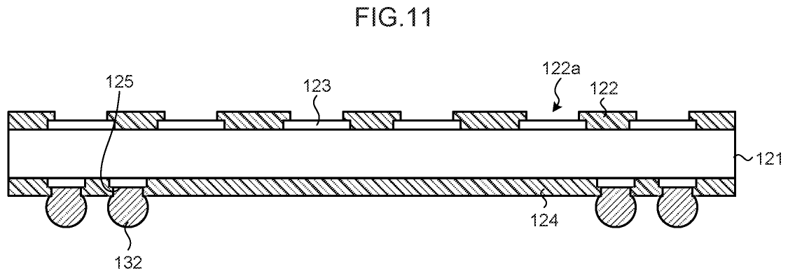

Through the processes as described above, as illustrated in FIG. 11 for example, the solder ball 132 (one example of the conductive ball) is bonded to the lower pad 125. With this configuration, the second wiring board 120 that forms the upper layer of the semiconductor device 100 is obtained. FIG. 11 is a diagram for explaining a solder ball mounting process.

Meanwhile, it is preferable to manufacture the second wiring board 120 as an assembly in which the plurality of the second wiring boards 120 are arrayed, instead of being manufactured singly. In the assembly, for example, the second wiring boards 120 are manufactured in respective sections that are divided in a lattice pattern.

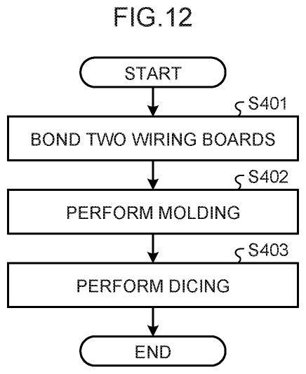

FIG. 12 is a flowchart illustrating a method of manufacturing the semiconductor device 100 according to one embodiment. The semiconductor device 100 is manufactured by using the first wiring board 110 and the second wiring board 120 as described above.

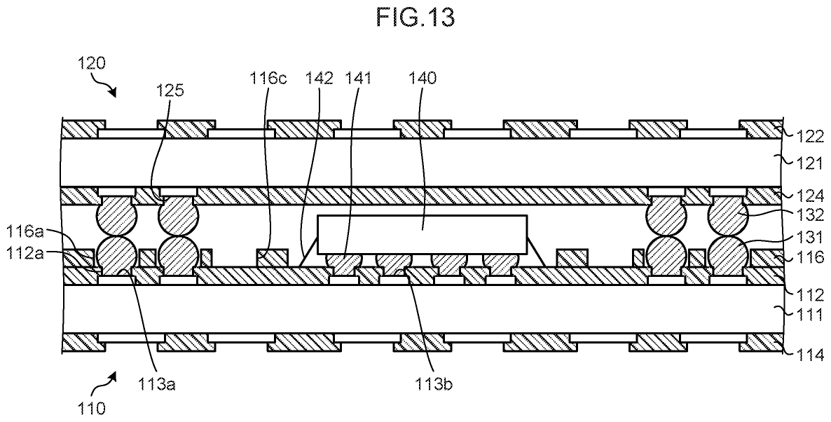

The first wiring board 110 and the second wiring board 120 are bonded together (Step S401). Firstly, as illustrated in FIG. 13 for example, the solder ball 132 that is bonded to the lower pad 125 of the second wiring board 120 is arranged on the solder ball 131 that is bonded to the upper pad 113a of the first wiring board 110, so that the second wiring board 120 is laminated on the first wiring board 110. FIG. 13 is a diagram for explaining lamination of the first wiring board 110 and the second wiring board 120. The electronic component 140 is arranged between the first wiring board 110 and the second wiring board 120.

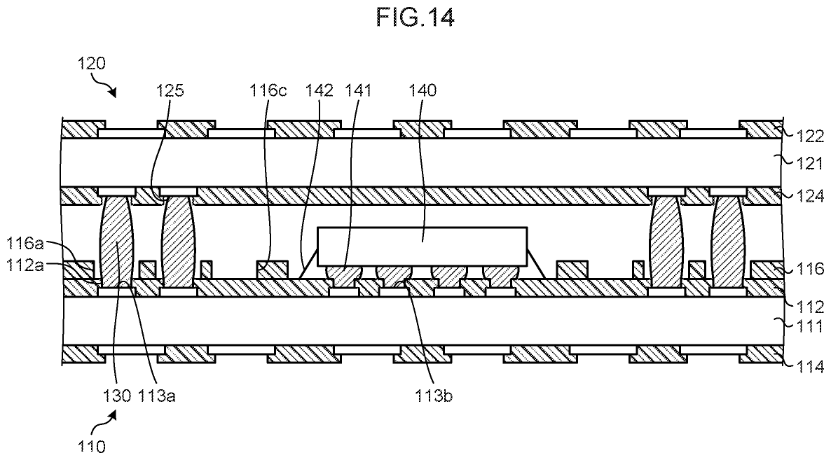

Subsequently, a reflow process is performed, so that the solder ball 131 and the solder ball 132 are melted and integrated, and the connection member 130 that is an integrated body is formed. Accordingly, as illustrated in FIG. 14 for example, the first wiring board 110 and the second wiring board 120 are bonded together by the connection member 130. FIG. 14 is a diagram for explaining a bonding process.

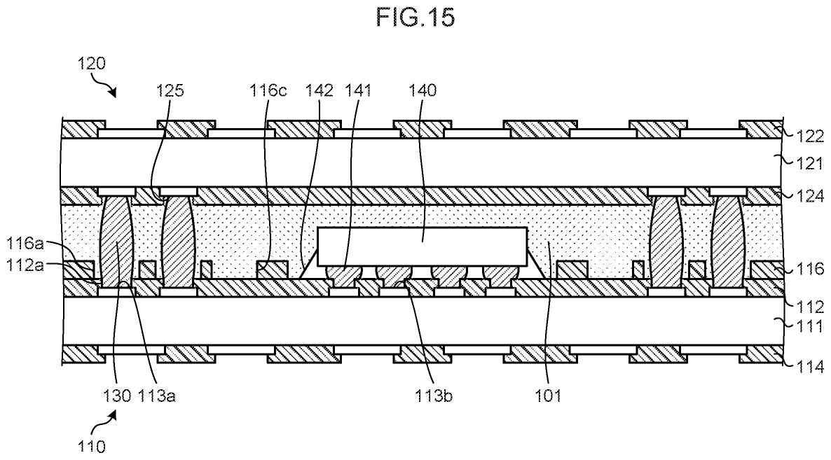

Further, for example, transfer molding is performed (Step S402), so that the gap between the first wiring board 110 and the second wiring board 120 is filled with the sealing resin 101. In the transfer molding, the first wiring board 110 and the second wiring board 120 that are bonded together are housed in a mold, and the liquefied sealing resin 101 is injected in the mold. Furthermore, the sealing resin 101 is heated to predetermined temperature (for example, 175 degrees Celsius) and cured. Accordingly, as illustrated in FIG. 15 for example, the gap between the first wiring board 110 and the second wiring board 120 is filled with the sealing resin 101, and the connection member 130 and the electronic component 140 are sealed. FIG. 15 is a diagram for explaining a molding process.

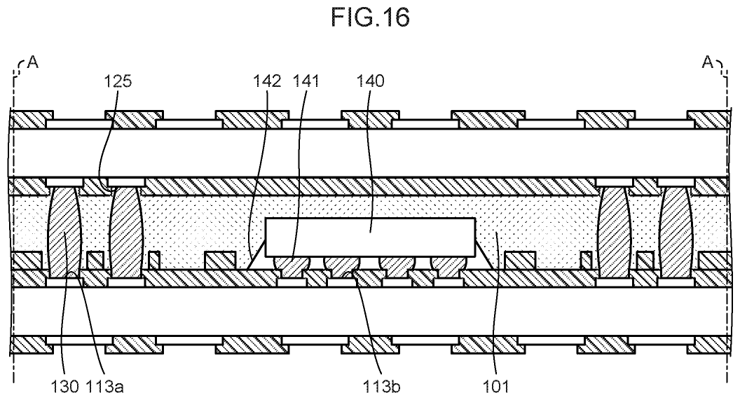

Through the processes as described above, as illustrated in FIG. 16 for example, a structure that is configured in the same manner as the semiconductor device 100 is obtained. The structure includes an assembly including the plurality of first wiring boards 110 and an assembly including the plurality of second wiring boards 120, and therefore, dicing for cutting out each of the first wiring board 110 and the second wiring board 120 (Step S403). FIG. 16 is a diagram for explaining a dicing process. Specifically, the structure illustrated in FIG. 16 is cut by, for example, a dicer or a slicer at a cutting plane line A that is located outside relative to the connection member 130, so that the semiconductor device 100 is obtained.

### Modifications

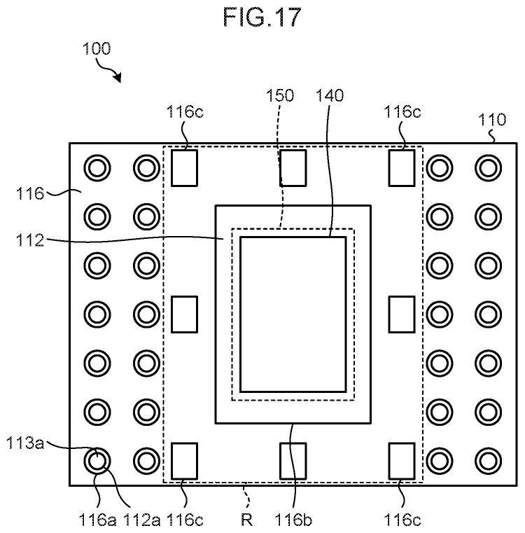

Various modifications of one embodiment will be described below with reference to FIG. 17 to FIG. 19. Meanwhile, in the modifications described below, the same components as those of one embodiment will be denoted by the same reference symbols, and repeated explanation will be omitted appropriately.

In the semiconductor device 100 according to one embodiment, the example has been described in which the plurality of openings 116c are formed at the four corners of the region R on the surface of the first wiring board 110, but the positions of the opening 116c are not limited to this example. Specifically, as illustrated in FIG. 17 for example, in the semiconductor device 100 according to a first modification, the plurality of openings 116c may be formed so as to face each other at around centers of the respective sides of the region R, in addition to the four corners of the region R on the surface of the first wiring board 110. FIG. 17 is a plan view illustrating a configuration of the semiconductor device 100 according to the first modification of one embodiment.

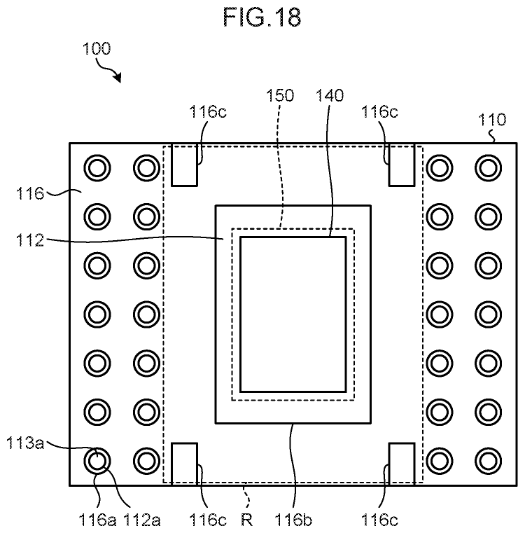

Furthermore, as illustrated in FIG. 18 for example, in the semiconductor device 100 according to a second modification, the openings 116c may be connected to an outer periphery of the first wiring board 110. FIG. 18 is a plan view illustrating a configuration of the semiconductor device 100 according to the second modification of one embodiment. In the example illustrated in FIG. 18, the openings 116c form notched shapes in the outer periphery of the first wiring board 110.

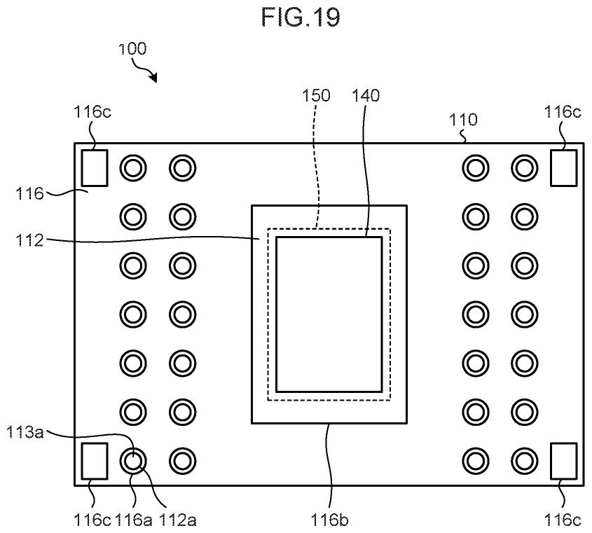

Moreover, as illustrated in FIG. 19 for example, in the semiconductor device 100 according to a third modification, the openings 116c may be formed at positions distant from the opening 116b relative to the openings 116a. FIG. 19 is a plan view illustrating a configuration of the semiconductor device 100 according to the third modification of one embodiment. In the example illustrated in FIG. 19, the plurality of openings 116c are formed at four corners of the surface of the first wiring board 110.

As described above, a semiconductor device (as one example, the semiconductor device 100) according to one embodiment includes a first wiring board (as one example, the first wiring board 110), an electronic component (as one example, the electronic component 140), a second wiring board (as one example, the second wiring board 120), and a connection member (as one example, the connection members 130). The electronic component is arranged on the first wiring board. The second wiring board faces the first wiring board across the electronic component. The connection member is an integrated object of conductive balls (as one example, the solder balls 131 and 132) that are mounted on the first wiring board and the second wiring board, and connects the first wiring board and the second wiring board. The first wiring board includes a wiring layer, a first insulating layer (as one example, the first protective insulating layer 112), and a second insulating layer (as one example, the second protective insulating layer 116). The wiring layer includes a pad (as one example, the upper pads 113a) to which the conductive ball (as one example, the solder balls 131) that forms the connection member is formed. The first insulating layer covers the wiring layer and includes a first opening (as one example, the openings 112a) for exposing the pad. The second insulating layer is laminated on the first insulating layer, and includes a second opening (as one example, the openings 116a) for exposing the pad and a surface of the first insulating layer around the first opening, and a third opening (as one example, the opening 116c) for exposing the surface of the first insulating layer at a different position from the second opening. With this configuration, it is possible to measure a height of the conductive ball (as one example, the solder balls 131) from the reference surface with high accuracy.

Furthermore, the surface of the first insulating layer exposed from the third opening may serve as a reference surface for measuring a height of the conductive ball. With this configuration, it is possible to measure the height of the conductive ball from the reference surface with increased accuracy.

Moreover, an area of the surface of the first insulating layer exposed from the third opening may be larger than an area of the surface of the first insulating layer exposed from the second opening. With this configuration, it is possible to measure the height of the conductive ball from the reference surface with increased accuracy.

Furthermore, the surface of the first insulating layer may include a mounting region (as one example, the mounting region 150) in which the electronic component is to be mounted. The second insulating layer may include a fourth opening (as one example, the opening 116b) for exposing the mounting region in the surface of the first insulating layer. The third opening may be formed at a position closer to the fourth opening relative to the second opening. With this configuration, it is possible to measure the height of the conductive ball from the reference surface with increased accuracy.

Moreover, the third opening may be formed at a position farther from the fourth opening relative to the second opening. With this configuration, it is possible to effectively use, as the reference surface, the surface of the first insulating layer exposed from the third opening that is formed at the position farther from the fourth opening relative to the second opening.

Furthermore, the second insulating layer may include the plurality of third openings that are formed at different positions. With this configuration, even when the reference surface is inclined, it is possible to measure the height of the conductive ball from the reference surface with high accuracy.

Moreover, the plurality of pads are formed along two opposing sides of the surface of the first wiring board. The first insulating layer may include the plurality of first openings that are formed so as to correspond to the respective pads. The second insulating layer may include the plurality of second openings that are formed so as to correspond to the respective first openings. The plurality of third openings may be formed in at least corner portions of an area (as one example, the area R) that is sandwiched between the pad formed along one of the two sides among the plurality of pads and the pad formed along the other one of the two sides. With this configuration, even when the reference surface is inclined, it is possible to measure the height of the conductive ball from the reference surface with high accuracy.

According to one aspect of the semiconductor device disclosed in the present application, it is possible to measure the height of the conductive ball from the reference surface with high accuracy.

(Note) (1) A semiconductor device manufacturing method comprising:
manufacturing a first wiring board on which an electronic component is arranged;
laminating a second wiring board on the first wiring board across the electronic component; and
bonding the first wiring board and the second wiring board by a connection member that is an integrated object of conductive balls that are mounted on the first wiring board and the second wiring board respectively, wherein
the manufacturing the first wiring board includes
   forming a wiring layer that includes a pad to which a conductive ball that forms the connection member is bonded;
   forming a first insulting layer that covers the wiring layer and includes a first opening for exposing the pad; and
   forming a second insulating layer that is laminated on the first insulating layer and includes a second opening for exposing the pad and a surface of the first insulating layer around the first opening, and a third opening for exposing a surface of the first insulating layer that is located at a different position from the second opening and that serves as a reference surface for measuring a height of the conductive ball.

(2) The semiconductor device manufacturing method according to the (1), wherein
the manufacturing the first wiring board includes:
   bonding the conductive ball to the pad; and
   measuring a height of the conductive ball bonded to the pad, and
the measuring the height of the conductive ball includes:
   applying light to the third opening;
   detecting reflected light from the reference surface exposed from the third opening;
   applying light to the conductive ball;
   detecting reflected light from the conductive ball; and
   calculating a height of the conductive ball from the reference surface based on a value related to a height of the reference surface that is measured by using the detected reflected light from the reference surface and a value related to a height of the conductive ball that is measured by using the detected reflected light from the conductive ball.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
a first wiring board;
an electronic component that is arranged on the first wiring board;
a second wiring board that faces the first wiring board across the electronic component; and
a connection member that is an integrated body of conductive balls that are mounted on the first wiring board and the second wiring board, respectively, and connects the first wiring board and the second wiring board, wherein
the first wiring board includes
a wiring layer that includes a pad to which a conductive ball that forms the connection member is bonded;
a first insulating layer that covers the wiring layer and includes a first opening for exposing the pad; and
a second insulating layer that is laminated on the first insulating layer, and includes
a second opening for exposing the pad and a surface of the first insulating layer around the first opening; and
a third opening for exposing a surface of the first insulating layer at a different position from the second opening.

2. The semiconductor device according to claim 1, wherein the surface of the first insulating layer exposed from the third opening serves as a reference surface for measuring a height of the conductive ball.

3. The semiconductor device according to claim 1, wherein an area of the surface of the first insulating layer exposed from the third opening is larger than an area of the surface of the first insulating layer exposed from the second opening.

4. The semiconductor device according to claim 1, wherein
the surface of the first insulating layer includes a mounting region in which the electronic component is to be mounted,
the second insulating layer includes a fourth opening for exposing the mounting region in the surface of the first insulating layer, and
the third opening is formed at a position closer to the fourth opening relative to the second opening.

5. The semiconductor device according to claim 1, wherein
the surface of the first insulating layer includes a mounting region in which the electronic component is to be mounted,
the second insulating layer includes a fourth opening for exposing the mounting region in the surface of the first insulating layer, and
the third opening is formed at a position farther from the fourth opening relative to the second opening.

6. The semiconductor device according to claim 1, wherein the second insulating layer includes a plurality of the third openings that are formed at different positions.

7. The semiconductor device according to claim 6, wherein
a plurality of the pads are formed along two opposing sides of the surface of the first wiring board,
the first insulating layer includes a plurality of the first openings that are formed so as to correspond to the plurality of the pads respectively,
the second insulating layer includes a plurality of the second openings that are formed so as to correspond to the plurality of the first openings, and
the plurality of the third openings are formed in at least corner portions of an area that is sandwiched between a pad formed along one of the two sides among the plurality of the pads and a pad formed along another one of the two sides among the plurality of the pads.
